(19) United States
(12) Patent Application Publication
(10) Pub. No.: US 2025/0040124 A1
(43) Pub. Date: Jan. 30, 2025

(54) GATE STRUCTURE AND SEMICONDUCTOR DEVICE INCLUDING THE SAME

(71) Applicant: Samsung Electronics Co., Ltd., Suwon-si (KR)

(72) Inventors: Dongsik Kong, Suwon-si (KR); Sungho Jang, Suwon-si (KR); Junsoo Kim, Suwon-si (KR); Junbum Lee, Suwon-si (KR); Jaehyun Choi, Suwon-si (KR); Ilgweon Kim, Suwon-si (KR); Jeonghoon Oh, Suwon-si (KR)

(21) Appl. No.: 18/442,274

(22) Filed: Feb. 15, 2024

(30) Foreign Application Priority Data
Jul. 28, 2023 (KR) 10-2023-0098900

(51) Int. Cl. H10B 12/00

(52) U.S. Cl. CPC H10B 12/34; H10B 12/02; H10B 12/315

(57) ABSTRACT

A gate structure includes a gate electrode on a substrate, the gate electrode including a lower portion and an upper portion sequentially stacked in a first direction substantially perpendicular to an upper surface of the substrate; a spacer structure including a second spacer and a first spacer sequentially stacked in a second direction substantially parallel to the upper surface of the substrate on a sidewall of the upper portion of the gate electrode; and a gate insulation pattern on a lower surface and a sidewall of the lower portion of the gate electrode and an outer sidewall of the spacer structure; wherein a cross-section of the first spacer has a shape of an “L”, and wherein the second spacer includes a material that is configured to induce a dipole at an interface of the first spacer and the gate insulation pattern.

### CROSS-REFERENCE TO RELATED APPLICATION

This application claims priority under 35 U.S.C. § 119 to Korean Patent Application No. 10-2023-0098900 filed on Jul. 28, 2023, in the Korean Intellectual Property Office, the disclosure of which is hereby incorporated by reference in its entirety.

### TECHNICAL FIELD

Example embodiments of the present disclosure relate to a gate structure and a semiconductor including the same.

### BACKGROUND

As the integration degree of DRAM devices gradually increases, the volume of a gate structure included in the DRAM device may decrease, and the distance between neighboring gate structures may decrease. Accordingly, resistance of the gate structure may increase and interference between the neighboring gate structures may increase.

### SUMMARY

Example embodiments provide a gate structure having improved characteristics.

Example embodiments provide a semiconductor device having improved characteristics.

According to example embodiments, there is provided a gate structure. The gate structure may include a gate electrode on a substrate, the gate electrode including a lower portion and an upper portion sequentially stacked in a first direction substantially perpendicular to an upper surface of the substrate; a spacer structure including a second spacer and a first spacer sequentially stacked in a second direction substantially parallel to the upper surface of the substrate on a sidewall of the upper portion of the gate electrode; and a gate insulation pattern on a lower surface and a sidewall of the lower portion of the gate electrode and an outer sidewall of the spacer structure; wherein a cross-section of the first spacer has a shape of an “L”, and wherein the second spacer includes a material that is configured to induce a dipole at an interface of the first spacer and the gate insulation pattern.

According to example embodiments, there is provided a gate structure. The gate structure may include a gate electrode on a substrate, the gate electrode including a first conductive pattern and a second conductive pattern sequentially stacked in a first direction substantially perpendicular to an upper surface of the substrate; a spacer structure contacting a sidewall of the second conductive pattern and an edge of an upper surface of the first conductive pattern, the spacer structure including a second spacer and a first spacer sequentially stacked in a second direction substantially parallel to the upper surface of the substrate; a gate insulation pattern on a lower surface and a sidewall of the first conductive pattern and an outer sidewall of the spacer structure; and a gate mask contacting an upper surface of the second conductive pattern and an upper surface of the spacer structure, wherein the upper surface of the spacer structure is substantially coplanar with the upper surface of the second conductive pattern, and wherein the first spacer includes a high dielectric material or silicon nitride, and the second spacer includes lanthanum oxide (LaO), magnesium oxide (MgO) or strontium oxide (SrO).

According to example embodiments, there is provided a semiconductor device. The semiconductor device may include an active pattern on a substrate; an isolation pattern on a sidewall of the active pattern; a gate structure extending in a first direction substantially parallel to an upper surface of the substrate in upper portions of the active pattern and the isolation pattern; a bit line structure on a central portion of the active pattern, the bit line structure extending in a second direction substantially parallel to the upper surface of the substrate and substantially perpendicular to the first direction; a contact plug structure on each of opposite end portions of the active pattern; and a capacitor structure on the contact plug structure. The gate structure may include a gate electrode extending in the first direction, the gate electrode including a lower portion and an upper portion sequentially stacked in a third direction substantially perpendicular to the upper surface of the substrate; a spacer structure including a second spacer and a first spacer sequentially stacked in the second direction on a sidewall of the upper portion of the gate electrode; and a gate insulation pattern on a lower surface and a sidewall of the lower portion of the gate electrode and an outer sidewall of the spacer structure; wherein a cross-section of the first spacer has a shape of an “L”, and wherein the second spacer includes a material that is configured to induce a dipole at an interface of the first spacer and the gate insulation pattern.

In a semiconductor device according to example embodiments, a gate structure may include a spacer structure disposed between a gate electrode and a gate insulation pattern, and the spacer structure may be configured to induce a dipole at an interface with the gate insulation pattern to decrease flat band voltage (Vmb) of the gate structure. Accordingly, the gate structure may have improved refresh time characteristics, and Gate Induced Drain Leakage (GIDL) may also be reduced or prevented.

In addition, the gate electrode may contain a metal or a metal nitride instead of polysilicon doped with impurities, and thus, the gate electrode may have generally low resistance. Accordingly, the gate structure may be formed to have a relatively small diameter, and thus, interference or risk of electrical short between neighboring gate structures may be reduced.

### BRIEF DESCRIPTION OF THE DRAWINGS

FIG. 1 is a cross-sectional view illustrating a gate structure in accordance with example embodiments.

FIGS. 2 to 4 are cross-sectional views illustrating a method of manufacturing a gate structure according to example embodiments.

FIGS. 5 and 6 are a plan view and a cross-sectional view, respectively, illustrating a semiconductor device in accordance with example embodiments.

FIGS. 7 to 22 are plan views and cross-sectional views illustrating a method of manufacturing a semiconductor device according to example embodiments.

### DETAILED DESCRIPTION

The above and other aspects and features of the semiconductor devices and the methods of manufacturing the same in accordance with example embodiments will become readily understood from detail description that follows with reference to the accompanying drawings. Like reference numerals in the drawings denote like elements, and thus their description will be omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination. It will be understood that, although the terms “first,” “second,” and/or “third” may be used herein to describe various directions, materials, layers, regions, pads, electrodes, patterns, structure and/or processes, these various materials, layers, regions, pads, electrodes, patterns, structure and/or processes should not be limited by these terms. These terms are only used to distinguish one direction, material, layer, region, pad, electrode, pattern, structure or process from another material, layer, region, pad, electrode, pattern, structure or process. Thus, “first”, “second” and/or “third” may be used selectively or interchangeably for each direction, material, layer, region, electrode, pad, pattern, structure or process respectively.

Hereinafter, two directions among horizontal directions that are substantially parallel to an upper surface of a substrate 10 or a substrate 100, which may be substantially orthogonal to each other, may be referred as first and second directions D1 and D2, respectively, and a direction among the horizontal directions, which may have an acute angle with respect to each of the first and second directions D1 and D2, may be referred to as a third direction D3. Additionally, a direction substantially perpendicular to the upper surface of the substrate 10 or the substrate 100 may be referred to as a vertical direction.

FIG. 1 is a cross-sectional view illustrating a gate structure in accordance with example embodiments.

Referring to FIG. 1, a gate structure 90 may be disposed in a first recess 5 extending into an upper portion of a substrate 10, and may include a gate insulation pattern 15, a spacer structure 50, a gate electrode 70 and a gate mask 80.

The substrate 10 may include silicon, germanium, silicon-germanium, and/or a III-V group compound semiconductor, such as GaP, GaAs, or GaSb. In example embodiments, the substrate 10 may be a silicon-on-insulator (SOI) substrate or a germanium-on-insulator (GOI) substrate.

The gate insulation pattern 15 may be disposed on a bottom and a sidewall of the first recess 5, and the gate electrode 70 and gate mask 80 may be sequentially stacked in the vertical direction on the gate insulation pattern 15 within the first recess 5.

The gate insulation pattern 15 may include, for example, an oxide, such as silicon oxide

The gate electrode may include a first conductive pattern 20 and a second conductive pattern 60 sequentially stacked in the vertical direction.

Each of the first and second conductive patterns 20 and 60 may include, for example, a metal nitride, such as titanium nitride (TiN), tantalum nitride (TaN), tungsten nitride (WN), etc., or a metal, such as tungsten (W), aluminum (Al), molybdenum (Mo), etc.

In one example embodiment, the first and second conductive patterns 20 and 60 may include substantially the same metal nitride or metal, and thus may be merged with each other to be integrally or monolithically formed. In another example embodiment, the first and second conductive patterns 20 and 60 may include different metal nitrides or metals from each other to be distinguished from each other, e.g., a boundary may be formed therebetween.

In some example embodiments, the first conductive pattern 20 or the second conductive pattern 60 may include a metal, for example, tungsten (W), aluminum (Al), molybdenum (Mo), etc. In this case, the gate electrode 70 may further include a barrier pattern at least partially covering a sidewall and/or a bottom of the metal. The barrier pattern may include a metal nitride, for example, titanium nitride, tantalum nitride, tungsten nitride, etc.

In example embodiments, an area of an upper surface of the first conductive pattern 20 may be greater than an area of a lower surface of the second conductive pattern 60.

The spacer structure 50 may be disposed between the gate insulation pattern 15 and the second conductive pattern 60, and may include a second spacer 45 and a first spacer 35 sequentially stacked in the second direction D2 on a sidewall of the second conductive pattern 60.

In example embodiments, the first spacer 35 may contact an inner sidewall of the gate insulation pattern 15 and an edge of the upper surface the first conductive pattern 20. A cross-section in the second direction D2 of the first spacer 35 may have a shape of an “L”. The second spacer 45 may contact an inner sidewall of the first spacer 35.

In example embodiments, the first spacer 35 may include a high dielectric material, for example, hafnium oxide, zirconium oxide, aluminum oxide, tantalum oxide, etc., or silicon nitride, and the second spacer 45 may include a material that induces a dipole, for example, lanthanum oxide, magnesium oxide, strontium oxide, etc.

The first and second spacers 35 and 45 may together be configured to induce a dipole at an interface of the first spacer 35 and the gate insulation pattern 15 to decrease a flat band voltage (V_{fb}) of the gate structure 90.

The gate mask 80 may include an insulating nitride, for example, silicon nitride.

If the gate electrode is composed of a first conductive pattern including a metal nitride and/or a metal, and a second conductive pattern including polysilicon doped with impurities that has a lower work function than that of the first conductive pattern, resistance of the second conductive pattern may be high, and thus, overall resistance of the gate electrode may be relatively high.

However, in the semiconductor device according to example embodiments, the gate electrode 70 may include the first and second conductive patterns 20 and 60, each of which includes a metal nitride and/or a metal, and thus, overall resistance of the gate electrode 70 may be relatively low. However, if the gate electrode 70 includes only a metal nitride and/or a metal and not include polysilicon doped with impurities having a low work function, refresh time may be deteriorated.

However, the gate structure 90 according to example embodiments may further include the spacer structure 50 disposed between the gate insulation pattern 15 and the gate electrode 70. The spacer structure 50 may lower the flat band voltage (V_{fb}) of the gate structure 90 by inducing a dipole at the interface with the gate insulation pattern 15. Accordingly, deterioration of the refresh time of the gate structure 90 may be reduced or prevented, and Gate Induced Drain Leakage (GIDL) may also be reduced or prevented.

In addition, the gate structure 90 may have a low resistance even if the gate structure 90 has a small diameter. Accordingly, the distance between the neighboring gate structures 90 may be sufficient, and thus, interference or electrical shorts therebetween may be reduced.

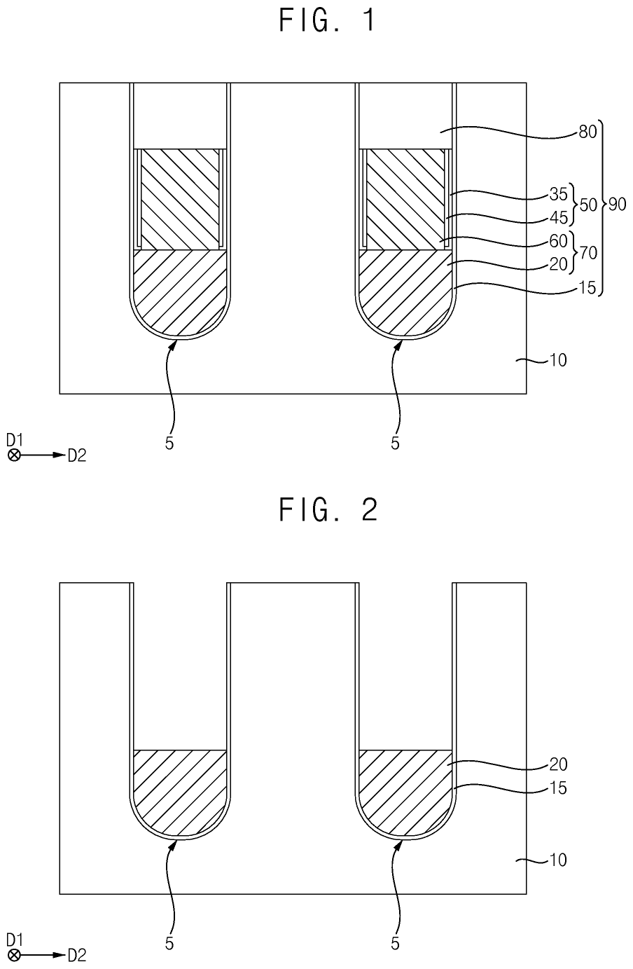

FIGS. 2 to 4 are cross-sectional views illustrating a method of manufacturing a gate structure in accordance with example embodiments.

Referring to FIG. 2, an upper portion of a substrate 10 may be partially removed to form a first recess 5, and a gate insulation pattern 15 may be conformally formed on an inner sidewall of the first recess 5.

A first conductive layer may be formed on the gate insulation pattern 15 and the substrate 10 to at least partially fill the first recess 5. An upper portion of the first conductive layer may be removed by, for example, performing an etch-back process to form a first conductive pattern 20 in a lower portion of the first recess 5. An upper surface of the first conductive pattern 20 may be lower than an upper surface of the substrate 10.

In example embodiments, the first conductive layer may be formed by a chemical vapor deposition (CVD) process, an atomic layer deposition (ALD) process, and/or a physical vapor deposition (PVD) process.

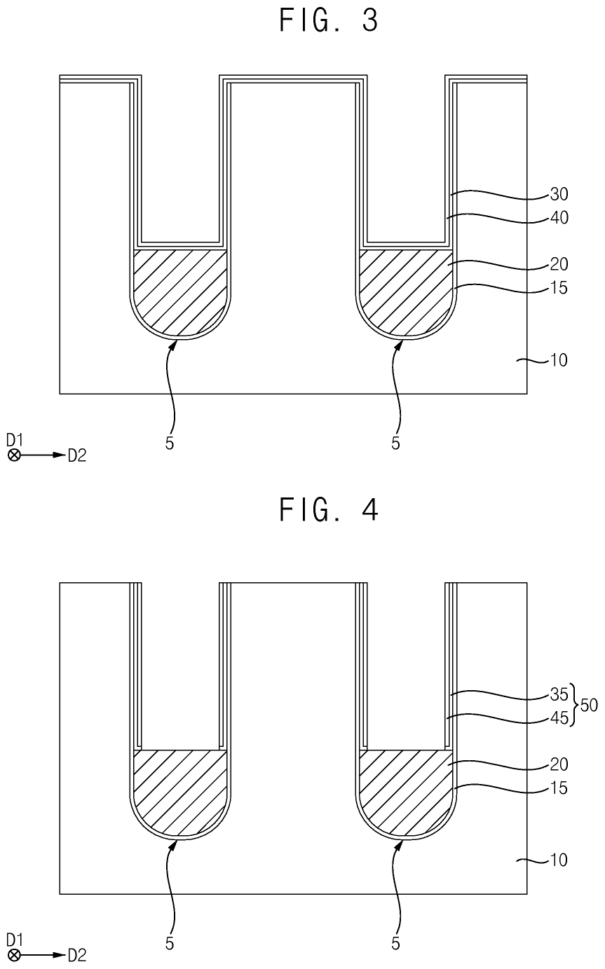

Referring to FIG. 3, a first spacer layer 30 may be formed on an upper surface of the first conductive pattern 20, an inner sidewall and an upper surface of the gate insulation pattern 15 and the upper surface of the substrate 10, and a second spacer layer 40 may be formed on the first spacer layer 30.

In example embodiments, each of the first and second spacer layers 30 and 40 may be formed by a chemical vapor deposition (CVD) process, an atomic layer deposition (ALD) process, and/or a physical vapor deposition (PVD) process.

Referring to FIG. 4, an anisotropic etching process may be performed on the first and second spacer layers 30 and 40 to form first and second spacers 35 and 45, respectively.

The first and second spacers 35 and 45 may together form a spacer structure 50. The first and second spacers 35 and 45 may be configured to induce a dipole at an interface of the first spacer 35 and the gate insulation pattern 15.

Referring again to FIG. 1, a second conductive layer may be formed on the first conductive pattern 20 to at least partially fill the first recess 5, and an upper portion of the second conductive layer may be removed by, for example, an etch-back process to form the second conductive pattern 60 in a middle portion of the first recess 5.

A gate mask layer may be formed on the second conductive pattern 60, the spacer structure 50, the gate insulation pattern 15 and the substrate 10 to at least partially fill a remaining portion of the first recess 5, and a planarization process may be performed on the gate mask layer until the upper surface of the substrate 10 is exposed to form a gate mask 80.

Accordingly, a gate structure 90 including the gate insulation pattern 15, the spacer structure 50 including the first and second spacers 35 and 45, the gate electrode 70 including the first and second conductive patterns 20 and 60, and a gate mask 80 may be formed.

The planarization process may include, for example, a chemical mechanical polishing (CMP) process and/or an etch-back process.

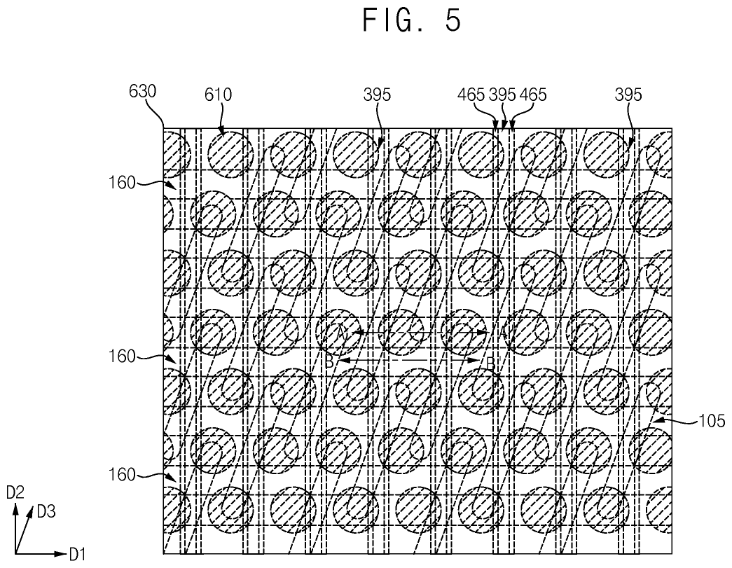

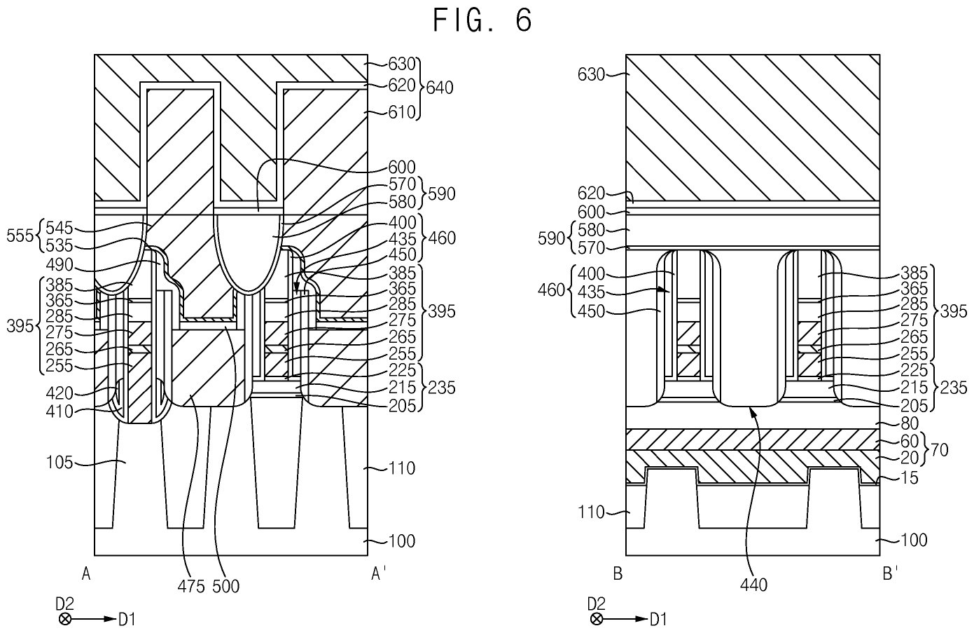

FIG. 5 is a plan view illustrating a semiconductor device in accordance with example embodiments, and FIG. 6 is a cross-sectional view taken along line A-A′ of FIG. 5.

This semiconductor device may be an application of the gate structure 90 illustrated with reference to FIG. 1 in a DRAM device, and thus repeated description of features of the gate structure is omitted herein.

Referring to FIGS. 1 and 2, the semiconductor device may include an active pattern 105, a gate structure 90, a bit line structure 395, a contact plug structure, and a capacitor 640 on the substrate 100.

The semiconductor device may further include an isolation pattern 110, a spacer structure 465, a sixth spacer 490, a second capping pattern 485, first and second insulation pattern structures 235 and 590, fourth and fifth insulation patterns 410 and 420, and a metal silicide pattern 500.

The active pattern 105 may extend in the third direction D3, and a plurality of active patterns 105 may be spaced apart from each other in the first and second directions D1 and D2. A sidewall of the active pattern 105 may be at least partially covered by the isolation pattern 110. The active pattern 105 may include substantially the same material as the substrate 100, and the isolation pattern 110 may include an oxide, e.g., silicon oxide.

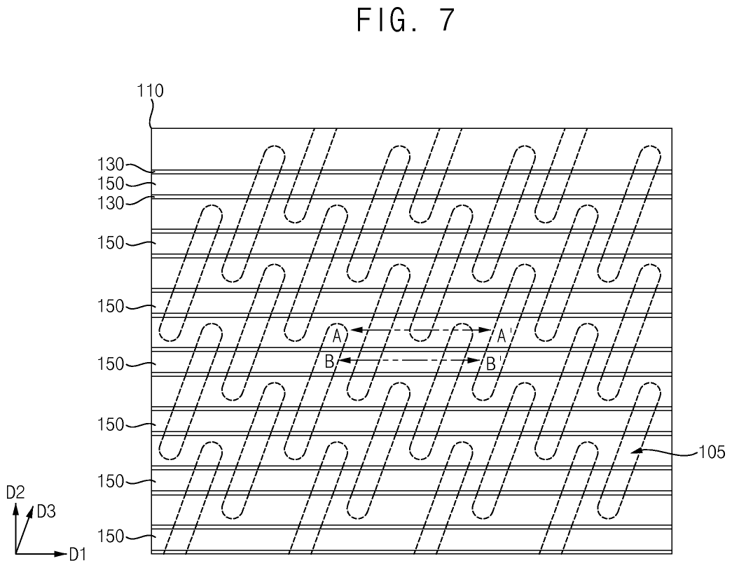

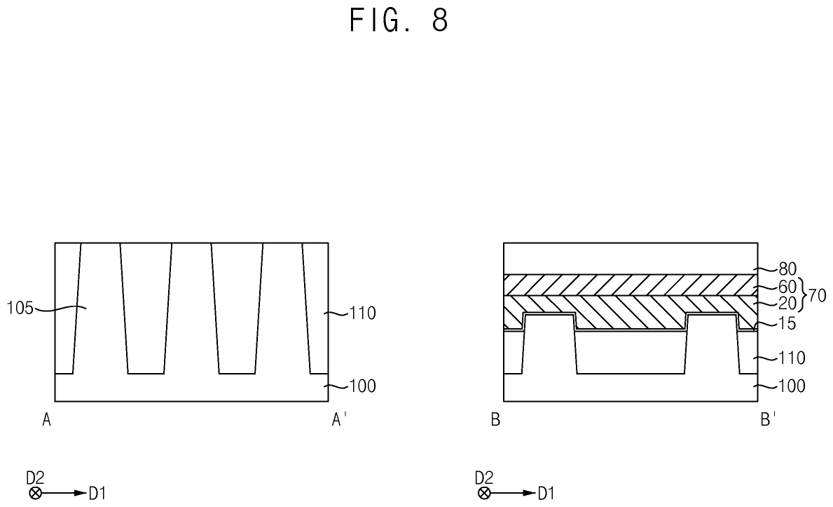

Referring to FIGS. 1 and 2 together with FIGS. 7 and 8, the gate structure 90 may be formed in a third recess extending in the first direction D1 through upper portions of the active pattern 105 and the isolation pattern 110. The gate structure 90 may include a gate insulation pattern 15 on a bottom and a sidewall of the third recess, a gate electrode 70 including first and second conductive patterns 20 and 60 on a portion of the gate insulation pattern 15 on the bottom and a lower sidewall of the third recess, and a gate mask 80 on the gate electrode 70 and at least partially filling an upper portion of the third recess.

In example embodiments, the gate structure 90 may extend in the first direction D1, and a plurality of gate structures 90 may be spaced apart from each other in the second direction D2.

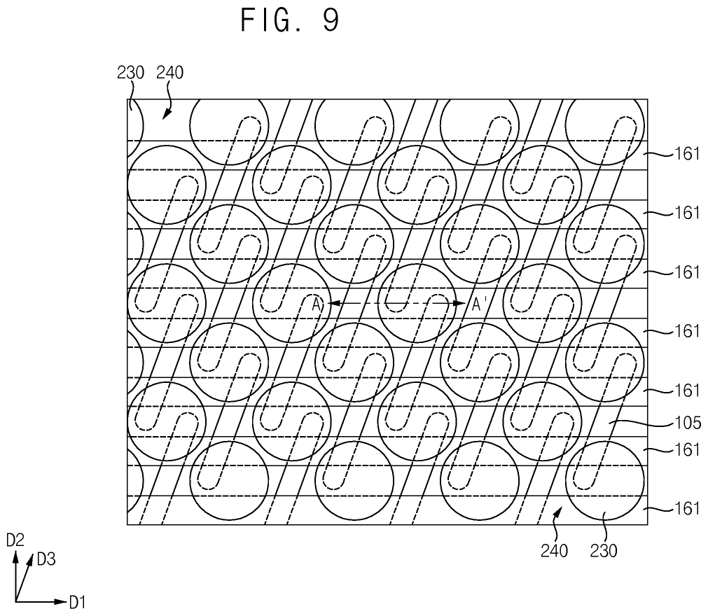

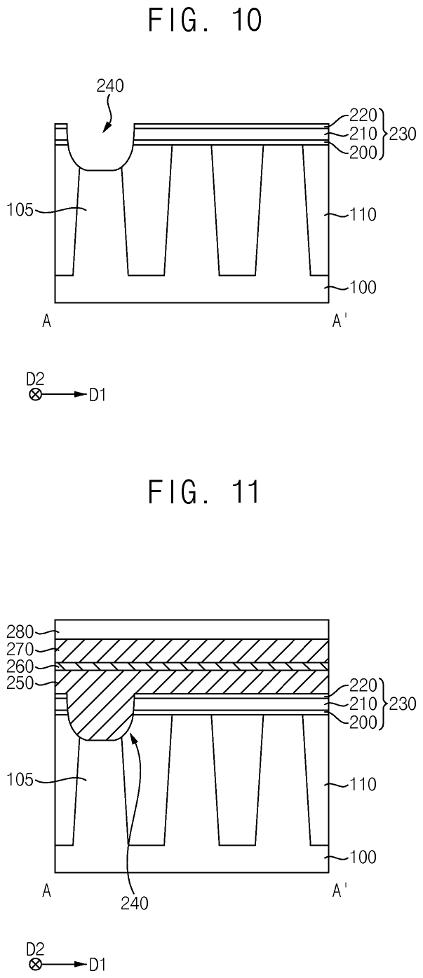

Referring to FIGS. 1 and 2 together with FIGS. 9 and 10, a first opening 240 extending through an insulation layer structure 230 and at least partially exposing upper surfaces of the active pattern 105, the isolation pattern 110 and the gate mask 80 of the gate structure 90 may be formed, and an upper surface of a central portion in the third direction D3 of the active pattern 105 may be at least partially exposed by the first opening 240.

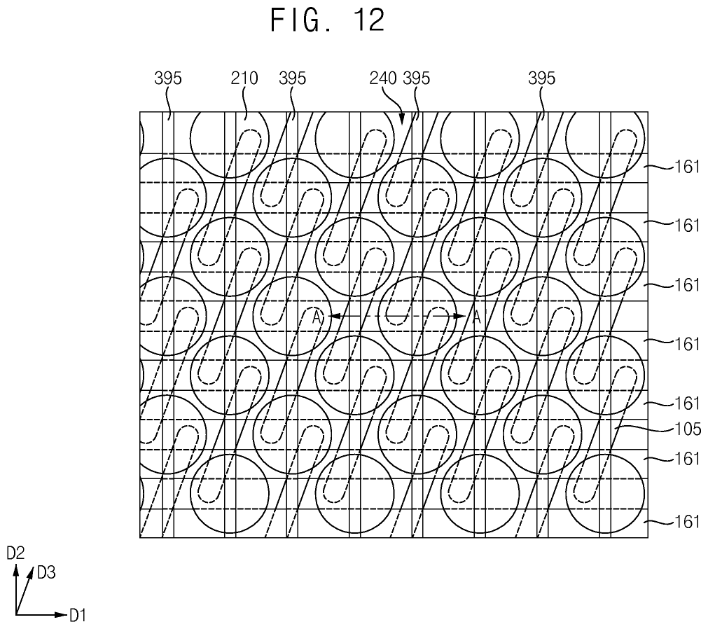

In example embodiments, an area of a bottom of the first opening 240 may be greater than an area of the upper surface of the active pattern 105. Thus, the first opening 240 may also at least partially expose an upper surface of a portion of the isolation pattern 110 adjacent to the active pattern 105. Additionally, the first opening 240 may extend through upper portions of the active pattern 105 and the portion of the isolation pattern 110 adjacent thereto, and thus the bottom of the first opening 240 may be lower than an upper surface of each of opposite edge portions in the third direction D3 of the active pattern 105 as shown in FIG. 11.

The bit line structure 395 may include a third conductive pattern 255, a first barrier pattern 265, a fourth conductive pattern 275, a first mask 285, a first etch stop pattern 365 and a first capping pattern 385 sequentially stacked in the vertical direction on the first opening 240 or the first insulation pattern structure 235. The third conductive pattern 255, the first barrier pattern 265 and the fourth conductive pattern 275 may collectively form a conductive structure, and the first mask 285, the first etch stop pattern 365 and the first capping pattern 385 may collectively form an insulation structure.

The third conductive pattern 255 may include, e.g., doped polysilicon, the first barrier pattern 265 may include a metal nitride, e.g., titanium nitride, or a metal silicon nitride, e.g., titanium silicon nitride, the fourth conductive pattern 275 may include a metal, e.g., tungsten, and each of the first mask 285, the first etch stop pattern 365 and the first capping pattern 385 may include an insulating nitride, e.g., silicon nitride.

In example embodiments, the bit line structure 395 may extend in the second direction D2 on the substrate 100, and a plurality of bit line structures 395 may be spaced apart from each other in the first direction D1.

The fourth and fifth insulation patterns 410 and 420 may be formed in the first opening 240, and may contact a lower sidewall of the bit line structure 395. The fourth insulation pattern 410 may include an oxide, e.g., silicon oxide, and the fifth insulation pattern 420 may include an insulating nitride, e.g., silicon nitride.

The first insulation pattern structure 235 may be formed on the active pattern 105 and the isolation pattern 110 under the bit line structure 395, and may include first, second and third insulation patterns 205, 215 and 225 sequentially stacked in the vertical direction. The first and third insulation patterns 205 and 225 may include an oxide, e.g., silicon oxide, and the second insulation pattern 215 may include an insulating nitride, e.g., silicon nitride.

The contact plug structure may include a lower contact plug 475, a metal silicide pattern 500 and an upper contact plug 555 sequentially stacked in the vertical direction on the active pattern 105 and the isolation pattern 110.

The lower contact plug 475 may contact the upper surface of each of opposite edge portions in the third direction D3 of the active pattern 105. In example embodiments, a plurality of lower contact plugs 475 may be spaced apart from each other in the second direction D2, and a second capping pattern 485 may be formed between neighboring ones of the lower contact plugs 475 in the second direction D2. The second capping pattern 485 may include an insulating nitride, e.g., silicon nitride.

The lower contact plug 475 may include, e.g., doped polysilicon, the metal silicide pattern 500 may include, e.g., titanium silicide, cobalt silicide, nickel silicide, etc.

The upper contact plug 555 may include a second metal pattern 545 and a second barrier pattern 535 at least partially covering a lower surface of the second metal pattern 545. The second metal pattern 545 may include a metal, e.g., tungsten, and the second barrier pattern 535 may include a metal nitride, e.g., titanium nitride.

In example embodiments, a plurality of upper contact plugs 555 may be spaced apart from each other in the first and second directions D1 and D2, and may be arranged in a honeycomb pattern or a lattice pattern in a plan view. Each of the upper contact plugs 555 may have a shape of, e.g., a circle, an ellipse, or a polygon in a plan view.

The spacer structure 465 may include a third spacer 400 at least partially covering sidewalls of the bit line structure 395 and the third insulation pattern 225, an air spacer 435 on a lower outer sidewall of the third spacer 400, and a fifth spacer 450 on an outer sidewall of the air spacer 435, a sidewall of the first insulation pattern structure 235, and upper surfaces of the fourth and fifth insulation patterns 410 and 420.

Each of the third and fifth spacers 400 and 450 may include an insulating nitride, e.g., silicon nitride, and the air spacer 435 may include air.

The sixth spacer 490 may be formed on an outer sidewall of a portion of the third spacer 400 on an upper sidewall of the bit line structure 395, and may at least partially cover an upper end of the air spacer 435 and an upper surface of the fifth spacer 450. The sixth spacer 490 may include an insulating nitride, e.g., silicon nitride.

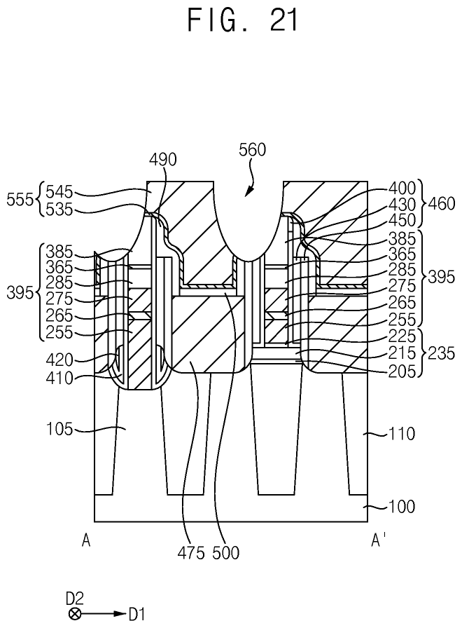

Referring to FIGS. 1 and 2 together with FIGS. 20 and 21, the second insulation pattern structure 590 may include a sixth insulation pattern 570 on an inner wall of sixth opening 560, which may extend through the upper contact plug 555, a portion of the insulation structure of the bit line structure 395 and portions of the third, fifth and sixth spacers 400, 450 and 490 and may at least partially surround the upper contact plug 555 in a plan view, and a seventh insulation pattern 580 on the sixth insulation pattern 570 and at least partially filling a remaining portion of the sixth opening 560. The upper end of the air spacer 435 may be closed by the sixth insulation pattern 570.

The sixth and seventh insulation patterns 570 and 580 may include an insulating nitride, e.g., silicon nitride.

The second etch stop pattern 600 may be formed on the sixth and seventh insulation patterns 570 and 580, the upper contact plug 555 and the second capping pattern 485. The second etch stop pattern 600 may include, for example, an insulating nitride, e.g., silicon boronitride, silicon nitride, etc.

The capacitor 640 may include a lower electrode 610, a dielectric layer 620 and an upper electrode 630 that are sequentially stacked, and the lower electrode 610 may extend through the second etch stop pattern 600 to contact an upper surface of the upper contact plug 555. Each of the lower electrode 610 and the upper electrode 630 may include, e.g., a metal, a metal nitride, a metal silicide, polysilicon doped with impurities, etc., and the dielectric layer 620 may include a metal oxide, for example, hafnium oxide, zirconium oxide, etc.

FIGS. 7 to 22 are plan views and cross-sectional views illustrating a method of manufacturing a semiconductor device according to example embodiments. Specifically, FIGS. 7, 9, 12, 16 and 20 are the plan views, FIG. 8 includes cross-sectional views taken along lines A-A′ and B-B′, respectively, of FIG. 7, and FIGS. 10-11, 13-15, 17-19 and 21-22 are cross-sectional views taken along lines A-A′, respectively, of corresponding plan views, respectively.

This semiconductor device may be an application of the method of manufacturing the gate structure 90 illustrated with reference to FIGS. 1 to 4 to a DRAM device, and thus repeated description of features of the method of manufacturing the gate structure 90 is omitted herein.

Referring to FIGS. 7 and 8, an upper portion of a substrate 100 may be removed to form a second recess, and an isolation pattern 110 may be formed in the second recess.

As the isolation pattern 110 is formed on the substrate 100, an active pattern 105 of which a sidewall is at least partially covered by the isolation pattern 110 may be defined.

The active pattern 105 and the isolation pattern 110 on the substrate 100 may be partially etched to form a third recess extending in the first direction D1, and a gate structure 90 may be formed in the third recess. In example embodiments, the gate structure 90 may extend in the first direction D1, and a plurality of gate structures may be spaced apart from each other in the second direction D2.

Referring to FIGS. 9 and 10, an insulating layer structure 230 may be formed on the active pattern 105, the isolation pattern 110, and the gate structure 90. The insulating layer structure 230 may include first to third insulating layers 200, 210, and 220 sequentially stacked.

The insulating layer structure 230 may be patterned, and the active pattern 105, the isolation pattern 110, and the gate mask 80 included in the gate structure 90 may be partially etched using the patterned insulating layer structure 230 as an etching mask to form a first opening 240. In example embodiments, the insulating layer structure 230 may have a circular shape or an elliptical shape in a plan view, and a plurality of insulating layer structures 230 may be spaced apart from each other in the first and second direction D1 and D2. Each of the insulating layer structures 230 may overlap edge portions of ones of the active patterns 105 neighboring in the third direction D3, which may face each other, in a vertical direction substantially orthogonal to the upper surface of the substrate 100.

Referring to FIG. 11, a third conductive layer 250, a first barrier layer 260, a fourth conductive layer 270 and a first mask layer 280 may be sequentially stacked on the insulating layer structure 230, and the active pattern 105, the isolation pattern 110 and the gate structure 90 may be exposed by the first opening 240. The third conductive layer 250 may at least partially fill the first opening 240.

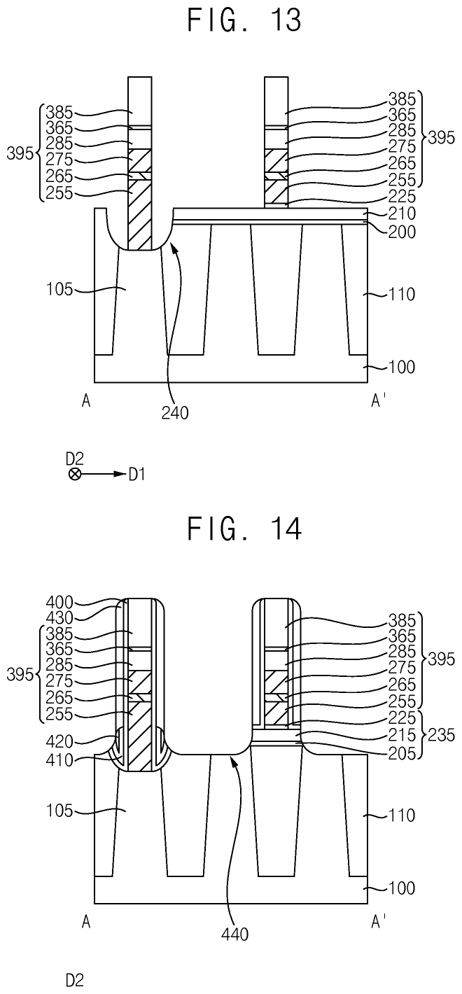

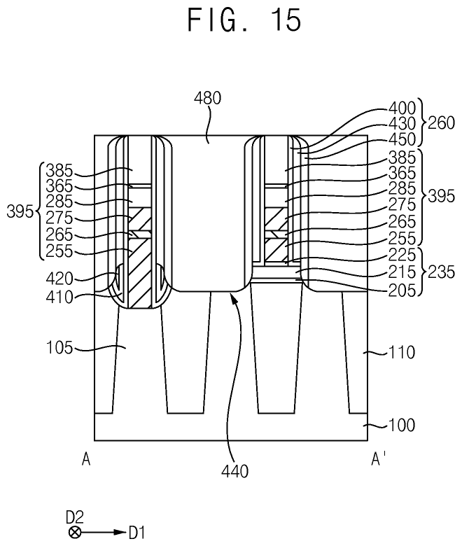

Referring to FIGS. 12 and 13, a first etch stop layer and a first capping layer may be sequentially formed on the conductive structure layer, the first capping layer may be etched to form a first capping pattern 385, and the first etch stop layer, the first mask layer 280, the fourth conductive layer 270, the first barrier layer 260 and the third conductive layer 250 may be sequentially etched using the first capping pattern 385 as an etching mask.

In example embodiments, the first capping pattern 385 may extend in the second direction D2, and a plurality of first capping patterns 385 may be spaced apart from each other in the first direction D1.

By the etching process, a third conductive pattern 255, a first barrier pattern 265, a fourth conductive pattern 275, a first mask 285, a first etch stop pattern 365 and the first capping pattern 385 may be formed on the first opening 240, and a third insulation pattern 225, the third conductive pattern 255, the first barrier pattern 265, the fourth conductive pattern 275, the first mask 285, the first etch stop pattern 365 and the first capping pattern 385 may be sequentially stacked on the second insulating layer 210 of the insulating layer structure 230 at an outside of the first opening 240.

Hereinafter, the third conductive pattern 255, the first barrier pattern 265, the fourth conductive pattern 275, the first mask 285, the first etch stop pattern 365 and the first capping pattern 385 sequentially stacked may be referred to as a bit line structure 395. The third conductive pattern 255, the first barrier pattern 265 and the fourth conductive pattern 275 may form a conductive structure, and the first mask 285, the first etch stop pattern 365 and the first capping pattern 385 may form an insulation structure. In example embodiments, the bit line structure 395 may extend in the second direction D2, and a plurality of bit line structures 395 may be spaced apart from each other in the first direction D1.

Referring to FIG. 14, a third spacer layer may be formed on the substrate 100 on which the bit line structure 395 is formed, and fourth and fifth insulating layers may be sequentially formed on the third spacer layer.

The third spacer layer may also at least partially cover a sidewall of the third insulation pattern 225 under the bit line structure 395 on the second insulating layer 210, and the fifth insulating layer may at least partially fill a remaining portion of the first opening 240.

The fourth and fifth insulating layers may be etched by an etching process. In example embodiments, the etching process may be a wet etching process using, for example, phosphoric acid (H₂PO₃), SC1, and hydrofluoric acid (HF) as an etchant, and portions of the fourth and fifth insulating layers except for portions thereof in the first opening 240 may be removed. Accordingly, most portion of a surface of the third spacer layer, that is, all portions of the surface of the third spacer layer except for a portion of the surface thereof in the first opening 240 may be at least partially exposed, and the fourth and fifth insulating layers remaining in the first opening 240 may form fourth and fifth insulation patterns 410 and 420, respectively.

A fourth spacer layer may be formed on the exposed surface of the fourth spacer layer and the fourth and fifth insulation patterns 410 and 420 in the first opening 240. The fourth spacer layer may be anisotropically etched to form a fourth spacer 430 at least partially covering a sidewall of the bit line structure 395 on the surface of the third spacer layer and on the fourth and fifth insulation patterns 410 and 420.

A dry etching process may be performed using the first capping pattern 385 and the fourth spacer 430 as an etching mask to form a second opening 440 at least partially exposing an upper surface of the active pattern 105, and upper surfaces of the isolation pattern 110 the gate mask 80 may also be at least partially exposed by the second opening 440.

By the dry etching process, portions of the third spacer layer on upper surfaces of the first capping pattern 385 and the second insulating layer 210 may be removed, and thus a third spacer 400 may be formed on the sidewall of the bit line structure 395. By the dry etching process, the first and second insulating layers 200 and 210 may be partially removed to remain as first and second insulation patterns 205 and 215, respectively, under the bit line structure 395. The first to third insulation patterns 205, 215 and 225 sequentially stacked under the bit line structure 395 may collectively form a first insulation pattern structure.

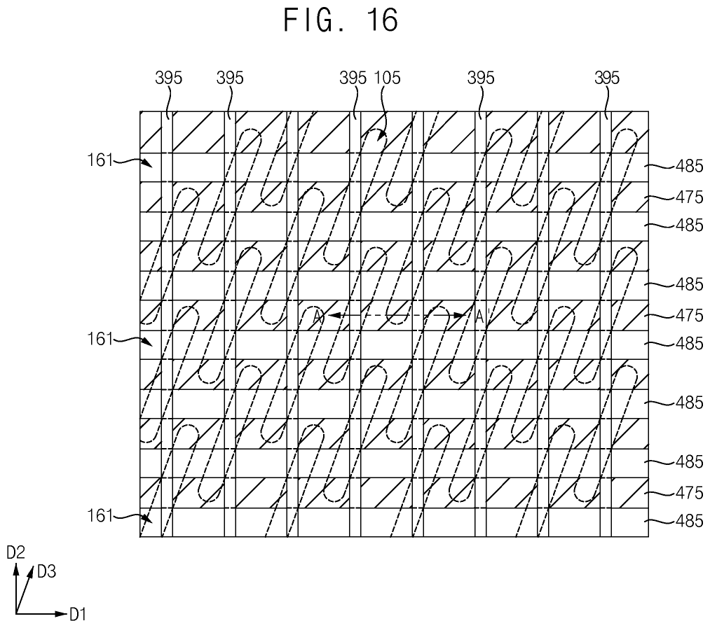

Referring to FIG. 15, a fifth spacer layer may be formed on an upper surface of the first capping pattern 385, an outer sidewall of the fourth spacer 430, portions of the upper surfaces of the fourth and fifth insulation patterns 410 and 420, and upper surfaces of the active pattern 105, the isolation pattern 110 and the gate mask 80 exposed by the second opening 440. The fifth spacer layer may be anisotropically etched to form a fifth spacer 450 at least partially covering the sidewall of the bit line structure 395.

The third to fifth spacers 400, 430 and 450 sequentially stacked on the sidewall of the bit line structure 395 in the horizontal direction may be referred to as a preliminary spacer structure 460.

A first sacrificial layer may be formed to at least partially fill the second opening 440 on the substrate 100 to a sufficient height, and an upper portion of the first sacrificial layer may be planarized until the upper surface of the first capping pattern 385 is exposed to form a first sacrificial pattern 480 in the second opening 440.

In example embodiments, the first sacrificial pattern 480 may extend in the second direction D2, and a plurality of first sacrificial patterns 480 may be spaced apart from each other in the first direction D1 by the bit line structures 395. The first sacrificial pattern 480 may include, for example, an oxide such as silicon oxide.

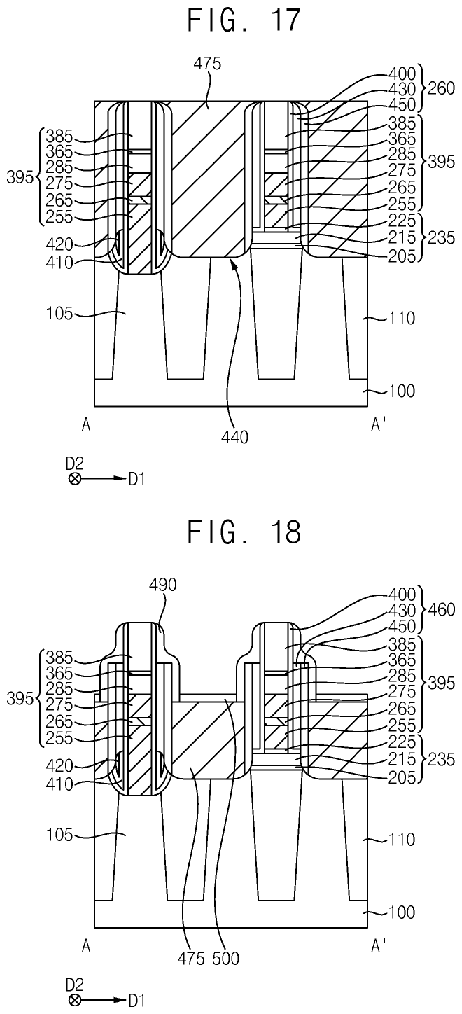

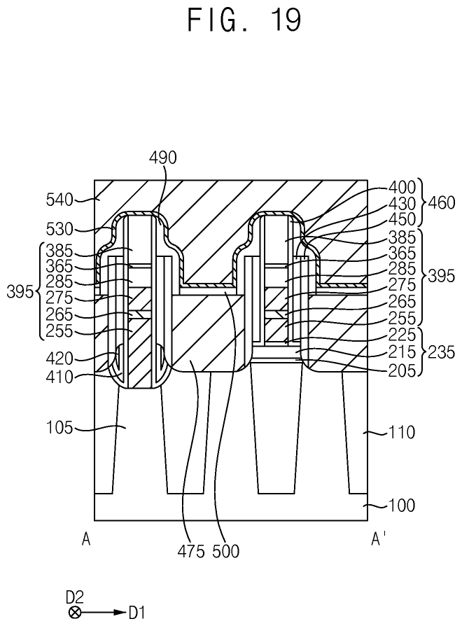

Referring to FIGS. 16 and 17, a second mask including a plurality of third openings, each of which may extend in the first direction D1, spaced apart from each other in the second direction D2 may be formed on the first capping pattern 385, the first sacrificial pattern 480, and the preliminary spacer structure 460, and may be etched using the second mask as an etching mask.

In example embodiments, each of the third openings may overlap a region between the gate structures 90 in the vertical direction. By the etching process, a fourth opening exposing upper surfaces of the active pattern 105 and the isolation pattern 110 may be formed between the bit line structures 395 on the substrate 100.

The second mask may be removed, a lower contact plug layer may be formed to at least partially fill the fourth opening to a sufficient height, and an upper portion of the lower contact plug layer may be planarized until the upper surface of the first capping pattern 385 and upper surfaces of the first sacrificial pattern 480 and the preliminary spacer structure 460 are at least partially exposed. Thus, the lower contact plug layer may be transformed into a plurality of lower contact plugs 475 spaced apart from each other in the second direction D2 between the bit line structures 395. Additionally, the first sacrificial pattern 480 extending in the second direction D2 between the bit line structures 395 may be divided into a plurality of pieces in the second direction D2 by the lower contact plugs 475.

The first sacrificial pattern 480 may be removed to form a fifth opening, and a second capping pattern 485 may be formed to at least partially fill the fifth opening. In example embodiments, the second capping pattern 485 may overlap the gate structure 90 in the vertical direction.

Referring to FIG. 18, an upper portion of the lower contact plug 475 may be removed to at least partially expose an upper portion of the preliminary spacer structure 460 on the sidewall of the bit line structure 395, and upper portions of the fourth and fifth spacers 430 and 450 of the exposed preliminary spacer structure 460 may be removed.

An upper portion of the lower contact plug 475 may be additionally removed. Thus, an upper surface of the lower contact plug 475 may be lower than upper surfaces of the fourth and fifth spacers 430 and 450 in the vertical direction.

A sixth spacer layer may be formed on the bit line structure 395, the preliminary spacer structure 460, the second capping pattern 485 and the lower contact plug 475, and may be anisotropically etched to form a sixth spacer 490 at least partially covering an upper portion of the preliminary spacer structure 460 on the sidewall of the bit line structure 395, and the upper surface of the lower contact plug 475 may be at least partially exposed by the etching process.

A metal silicide pattern 500 may be formed on the exposed upper surface of the lower contact plug 475. In example embodiments, the metal silicide pattern 500 may be formed by forming a first metal layer on the first and second capping patterns 385 and 485, the sixth spacer 490 and the lower contact plug 475, performing a heat treatment thereon, and removing an unreacted portion of the first metal layer.

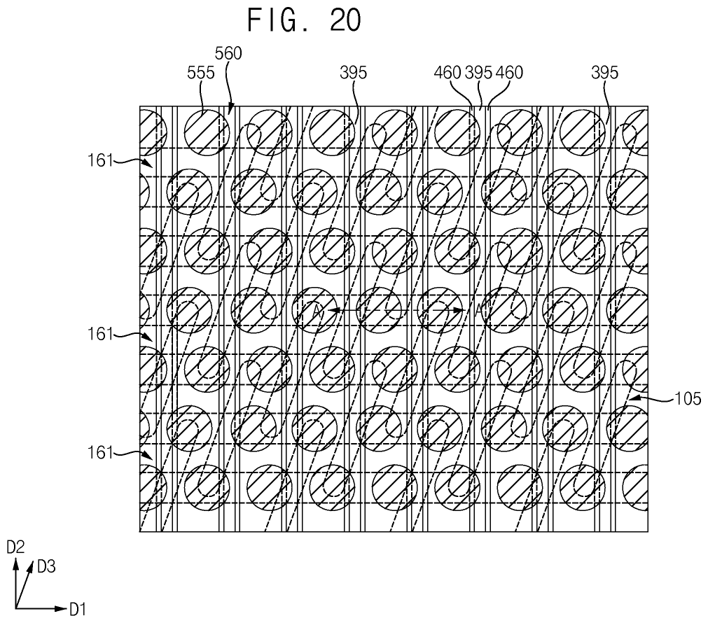

Referring to FIG. 19, a second barrier layer 530 may be formed on the first and second capping patterns 385 and 485, the sixth spacer 490, the metal silicide pattern 500 and the lower contact plug 475, and a second metal layer 540 may be formed on the second barrier layer 530 to at least partially fill a space between the bit line structures 395.

A planarization process may be performed on an upper portion of the second metal layer 540. The planarization process may include, for example, a chemical mechanical polishing (CMP) process and/or an etch-back process.

Referring to FIGS. 20 and 21, the second metal layer 540 and the second barrier layer 530 may be patterned to form an upper contact plug 555. In example embodiments, a plurality of upper contact plugs 555 may be formed, and a sixth opening 560 may be formed between the upper contact plugs 555.

The sixth opening 560 may be formed by partially removing the first and second capping patterns 385 and 485, the preliminary spacer structure 460 and the sixth spacer 490, as well as the second metal layer 540 and the second barrier layer 530.

The upper contact plug 555 may include a second metal pattern 545 and a second barrier pattern 535 at least partially covering a lower surface of the second metal pattern 545. In example embodiments, the upper contact plug 555 may have a shape of a circle, an ellipse, or a rounded polygon in a plan view, and the upper contact plugs 555 may be arranged, for example, in a honeycomb pattern in the first and second direction D1 and D2, in a plan view.

The lower contact plug 475, the metal silicide pattern 500 and the upper contact plug 555 sequentially stacked on the substrate 100 may collectively form a contact plug structure.

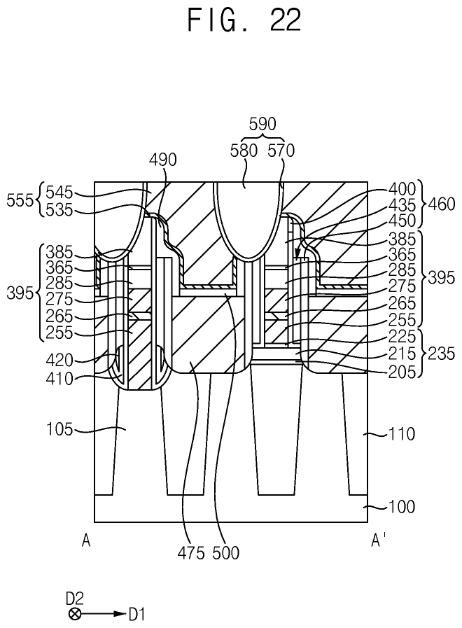

Referring to FIG. 22, the fourth spacer 430 included in the preliminary spacer structure 460 exposed by the sixth opening 560 may be removed to form an air gap, a sixth insulation pattern 570 may be formed on a bottom and a sidewall of the sixth opening 560, and a seventh insulation pattern 580 may be formed to at least partially fill a remaining portion of the sixth opening 560.

Each of the sixth and seventh insulation patterns 570 and 580 may form a second insulation pattern structure 590.

A top end of the air gap may be at least partially covered by the sixth insulation pattern 570, and thus an air spacer 435 may be formed. The third spacer 400, the air spacer 435 and the fifth spacer 450 may collectively form a spacer structure 465.

Referring again to FIGS. 5 and 6, a second etch stop pattern 600 and a mold layer may be sequentially formed on the second insulating pattern structure 590 and the upper contact plug 555, a seventh opening may be formed to at least partially expose an upper surface of the upper contact plug 555, and a lower electrode 610 may be formed in the seventh opening.

The mold layer may be removed, and a dielectric layer 620 and an upper electrode 630 may be formed on the lower electrode 610 and the second etch stop pattern 600. Accordingly, the capacitor 640 including the lower electrode 610, the dielectric layer and the upper electrode 630 may be formed, and the manufacturing of the semiconductor device may be completed.

While embodiments of the inventive concept have been particularly shown and described with reference to embodiments thereof, it will be understood that various changes in form and details may be made therein without departing from the spirit and scope of the following claims.

What is claimed is:

1. A gate structure, comprising:
a gate electrode on a substrate, the gate electrode including a lower portion and an upper portion sequentially stacked in a first direction substantially perpendicular to an upper surface of the substrate;
a spacer structure including a second spacer and a first spacer sequentially stacked in a second direction substantially parallel to the upper surface of the substrate on a sidewall of the upper portion of the gate electrode; and
a gate insulation pattern on a lower surface and a sidewall of the lower portion of the gate electrode and an outer sidewall of the spacer structure;
wherein a cross-section of the first spacer has a shape of an “L”, and
wherein the second spacer includes a material that is configured to induce a dipole at an interface of the first spacer and the gate insulation pattern.

2. The gate structure of claim 1, wherein the spacer structure contacts an edge of an upper surface of the lower portion of the gate electrode.

3. The gate structure of claim 1, wherein the second spacer includes lanthanum oxide (LaO), magnesium oxide (MgO) or strontium oxide (SrO).

4. The gate structure of claim 3, wherein the first spacer includes a high dielectric material or silicon nitride.

5. The gate structure of claim 4, wherein the high dielectric material includes hafnium oxide (HfO), zirconium oxide (ZrO), aluminum oxide (AlO) or tantalum oxide (TaO).

6. The gate structure of claim 1, wherein an area of an upper surface of the lower portion of the gate electrode is greater than an area of a lower surface of the upper portion of the gate electrode.

7. The gate structure of claim 6, wherein the gate electrode includes a metal nitride or a metal.

8. The gate structure of claim 7, wherein the metal nitride includes titanium nitride (TiN), tantalum nitride (TaN) or tungsten nitride (WN), and the metal includes tungsten (W), aluminum (Al) or molybdenum (Mo).

9. The gate structure of claim 1, further comprising:
a gate mask on the gate electrode and the spacer structure,
wherein the gate insulation pattern is on a sidewall of the gate mask.

10. The gate structure of claim 1, wherein the upper portion of the gate electrode and the lower portion of the gate electrode include substantially a same material.

11. A gate structure, comprising:
a gate electrode on a substrate, the gate electrode including a first conductive pattern and a second conductive pattern sequentially stacked in a first direction substantially perpendicular to an upper surface of the substrate;
a spacer structure contacting a sidewall of the second conductive pattern and an edge of an upper surface of the first conductive pattern, the spacer structure including a second spacer and a first spacer sequentially stacked in a second direction substantially parallel to the upper surface of the substrate;
a gate insulation pattern on a lower surface and a sidewall of the first conductive pattern and an outer sidewall of the spacer structure; and
a gate mask contacting an upper surface of the second conductive pattern and an upper surface of the spacer structure,
wherein the upper surface of the spacer structure is substantially coplanar with the upper surface of the second conductive pattern, and
wherein the first spacer includes a high dielectric material or silicon nitride, and the second spacer includes lanthanum oxide (LaO), magnesium oxide (MgO) or strontium oxide (SrO).

12. The gate structure of claim 11, wherein the high dielectric material includes hafnium oxide (HfO), zirconium oxide (ZrO), aluminum oxide (AlO) or tantalum oxide (TaO).

13. The gate structure of claim 11, wherein a cross-section of the first spacer has a shape of an “L”.

14. The gate structure of claim 11, wherein each of the first and second conductive patterns include a metal nitride or a metal.

15. The gate structure of claim 14, wherein the metal nitride includes titanium nitride (TiN), tantalum nitride (TaN) and tungsten nitride (WN), and the metal includes at least one of tungsten (W), aluminum (Al) and molybdenum (Mo).

16. The gate structure of claim 11, wherein the first and second conductive patterns include substantially a same material.

17. The gate structure of claim 11, wherein the first and second conductive patterns include different materials.

18. A semiconductor device comprising:
an active pattern on a substrate;
an isolation pattern on a sidewall of the active pattern;
a gate structure extending in a first direction substantially parallel to an upper surface of the substrate in upper portions of the active pattern and the isolation pattern;
a bit line structure on a central portion of the active pattern, the bit line structure extending in a second direction substantially parallel to the upper surface of the substrate and substantially perpendicular to the first direction;
a contact plug structure on each of opposite end portions of the active pattern; and
a capacitor structure on the contact plug structure,
wherein the gate structure includes:
a gate electrode extending in the first direction, the gate electrode including a lower portion and an upper portion sequentially stacked in a third direction substantially perpendicular to the upper surface of the substrate;
a spacer structure including a second spacer and a first spacer sequentially stacked in the second direction on a sidewall of the upper portion of the gate electrode; and
a gate insulation pattern on a lower surface and a sidewall of the lower portion of the gate electrode and an outer sidewall of the spacer structure;
wherein a cross-section of the first spacer has a shape of an “L”, and
wherein the second spacer includes a material that is configured to induce a dipole at an interface of the first spacer and the gate insulation pattern.

19. The semiconductor device of claim 18, wherein the spacer structure contacts each edge in the second direction of an upper surface of the lower portion of the gate electrode.

20. The semiconductor device of claim 18, wherein the first spacer includes a high dielectric material or silicon nitride, and the second spacer includes lanthanum oxide (LaO), magnesium oxide (MgO) or strontium oxide (SrO).
